(19) United States
(12) Patent Application Publication
(10) Pub. No.: US 2024/0408712 A1
(43) Pub. Date: Dec. 12, 2024

(54) CERAMIC COOLING BASE

(71) Applicant: Applied Materials, Inc., Santa Clara, CA (US)

(72) Inventors: Andreas Schmid, Santa Clara, CA (US); Stephen Prouty, Santa Clara, CA (US); Alvaro Garcia de Gorordo, Santa Clara, CA (US); Andrew Antoine Noujaim, Santa Clara, CA (US)

(21) Appl. No.: 18/206,332

(22) Filed: Jun. 6, 2023

(51) Int. Cl. B23Q 11/10; B23Q 3/15; F28F 13/00; H02N 13/00

(52) U.S. Cl. CPC B23Q 11/10; B23Q 3/15; F28F 13/00; H02N 13/00; B33Y 10/00; B33Y 80/00; F28F 2013/001

(57) ABSTRACT

Substrate supports and related components including additive manufacturing processes are disclosed. One substrate support assembly includes an electrostatic chuck; and a cooling base having a first surface that is bonded to a first surface of the electrostatic chuck with a metallic bonding material, the cooling base comprising: a ceramic body having a coefficient of thermal expansion substantially the same as the electrostatic chuck; one or more cooling channels formed within the ceramic body; and one or more conductive zones extending through the ceramic body from the first surface to a second surface on an opposite side of the cooling base.

### BACKGROUND

This specification relates to semiconductor systems, processes, and equipment. Semiconductor fabrication can involve various processes performed on a substrate. These processes can take place in one or more processing chambers. For example, deposition processes can be performed to deposit layers of films of various materials on the substrate. In another example, plasma etching can be used in semiconductor processing to selectively etch one or more layers using a plasma formed from particular etching gas chemistries. As scaling of integrated circuits continues to move towards smaller features and increased aspect ratios, there is a growing need for precision in performing processes on the substrate.

### SUMMARY

This specification describes technologies for substrate supports and related components. These technologies generally involve using additive manufacturing techniques to design and fabricate substrate supports and components thereof for use in substrate processing chambers. Specifically, a cooling base of the substrate support can be formed from the same material as a substrate support body, e.g., an electrostatic chuck. For example, both can be formed from a ceramic material such as aluminum oxide (Al₂O₃), or aluminum nitride (AlN). Using the same material provides for a common coefficient of thermal expansion (CTE) between the two components of the substrate support. Moreover, the two common materials can be bonded using a metal bond, e.g., aluminum, allowing for low temperature substrate processing applications.

The cooling base can be formed using additive manufacturing and include various fluid pathways configured to provide closed loops for circulating fluids through the cooling base, embedded thermal brake structures, and electrically conductive regions. Furthermore, the additive manufacturing can optionally form a cooling base that incorporates lift pin guides into the structure of the cooling base.

As used in this specification, a substrate refers to a wafer or another carrier structure, e.g., a glass plate. A wafer can include a semiconductor material, e.g., Silicon, GaAs, InP, or another semiconductor-based wafer material. A wafer can include an insulator material, for example, silicon-on-insulator (SOI), diamond, etc. At times, the substrate includes film(s) formed on a surface of the wafer/carrier structure. The film(s) can be, for example, dielectric, conductive, or insulating films. The film(s) can be formed on the surface of the wafer using various deposition techniques, for example, spin-coating, atomic layer deposition (ALD), chemical vapor deposition (CVD), metal-organic chemical vapor deposition (MOCVD), molecular beam epitaxy (MBE), or other similar techniques for forming thin film layers on a wafer or another carrier structure. In some embodiments, the fabrications tools described in this specification are plasma-based etching tools, where etch processes can be performed on the formed layers on the surface of the wafer/carrier structure and/or on the wafer.

In general, one innovative aspect of the subject matter described in this specification can be embodied in an electrostatic chuck; and a cooling base having a first surface that is bonded to a first surface of the electrostatic chuck with a metallic bonding material, the cooling base including: a ceramic body having a coefficient of thermal expansion substantially the same as the electrostatic chuck; one or more cooling channels formed within the ceramic body; and one or more conductive zones extending through the ceramic body from the first surface to a second surface on an opposite side of the cooling base. In general, one innovative aspect of the subject matter described in this specification can be embodied in a substrate support component of a substrate support embodied in a machine-readable medium for designing, manufacturing, or testing a design, the substrate support component including: a cooling base wherein the insulator body is configured to support an electrostatic chuck on a first surface of the cooling base; one or more cooling channels embedded within the cooling base and configured to facilitate refrigerant flow within the cooling base; one or more first gas conduits formed within the cooling base and configured to facilitate gas flow through the cooling base and couple into one or more second gas conduits of the electrostatic chuck, when the electrostatic chuck is supported by the first surface; and one or more thermal isolation structures integrally formed within the cooling base and oriented to control thermal uniformity across the cooling base as provided by the refrigerant flowing through the one or more cooling channels.

In general, one innovative aspect of the subject matter described in this specification can be embodied in a method of manufacturing a substrate support, the method including: forming, by an additive manufacturing system, a plurality of layers, the plurality of layers including: a ceramic body; one or more cooling channels formed within the ceramic body and configured to circulate a refrigerant; one or more gas conduits formed within the ceramic body and configured to pass a gas through the ceramic body; and one or more conductive regions formed within the ceramic body and extending from a first surface of the substrate support to a second, opposing surface of the ceramic body.

The subject matter described in this specification can be implemented in these and other embodiments so as to realize one or more of the following advantages. Using additive manufacturing (AM) techniques to manufacture substrate supports can overcome challenges in the methods to manufacture the substrate supports and components of the substrate supports, improve yield, and increase complexity, as well as open up material possibilities. In one example, AM can be used to introduce features otherwise unavailable or cost-prohibited by traditional, non-AM techniques, e.g., embedded sensors, complex internal channels/conduits, etc.,

AM techniques can result in improved control over fidelity (e.g., defect reduction) of manufactured parts resulting in better performance of the manufactured parts, e.g., reduced helium leaks, improved capacitance, tighter (critical) dimensional control, reduced cracking due to machining, etc.

Additionally, AM techniques can be used to refurbish/regrow/modify existing substrate supports, which can result in increased lifetime of components and decreased costs by reusing rather than full replacement. The refurbishment/modification process can target localized degradation, e.g., due to use in a process environment and exposure to plasma and etch chemistries, to restore functionality of the substrate support for continued target performance and use. Localized AM-based regrowth techniques for refurbishment can reduce cost, material consumption, and time for the refurbishment. Additionally, refurbishments/modification can be used to update an existing component rather than fabricating a completely new component to incorporate a new feature.

Forming the cooling base from the same material as the electrostatic chuck (ESC) eliminates CTE mismatch as compared to using different materials (e.g., metallic cooling base vs. ceramic ESC). In addition to eliminating the CTE mismatch, using the same ceramic materials allows for the use of a metallic bond to couple the ESC to the cooling base. Using a metallic bond allows for lower operating temperatures for particular substrate processing operations as compared to the temperature range for other bonding materials, for example, elastomer bonds. For example, using a metallic bond the operating temperatures can include processing operations as low as-150 degrees Celsius as compared to a limit of-90 degrees Celsius for elastomer bonding. Additionally, elastomer bonds can be sources of processing chamber contamination as they corrode over time. Using a metallic bond can reduce this source of contamination. Additive manufacturing allows for incorporated lift pin guides at stricter tolerances that reduce the likelihood of binding between the lift pins and the lift pin guides. Additive manufacturing of the cooling base allows for various different cooling channel geometries that can provide more control over thermal distribution, e.g., when applying cooling to the cooling base. The cooling base can include internal structures formed through additive manufacturing that reduce weight while maintaining strength and thermal transfer characteristics. As a result, the cooling base can be manufactured at a reduced materials cost. Furthermore, additive manufacturing allows for tighter tolerances in forming structures. For example, cooling channels can be formed in closer proximity to other internal structures using additive manufacturing than is typically possible using other fabrication techniques.

Although the remaining disclosure will identify specific processes for etch-based fabrication tools using the disclosed technology, it will be readily understood that the systems and methods are equally applicable to a variety of other fabrication tools and chambers. Accordingly, the technology should not be considered to be so limited as for use with the described etching fabrication tools alone. The disclosure will discuss one possible system and chamber that can be used with the present technology before describing systems and methods or operations of exemplary process sequences according to some embodiments of the present technology. It is to be understood that the technology is not limited to the equipment described, and processes discussed can be performed in any number of processing chambers and systems.

### BRIEF DESCRIPTION OF THE DRAWINGS

FIG. 1 shows a schematic cross-sectional view of an example plasma processing chamber.

FIG. 2 shows a schematic cross-sectional view of an example support structure.

FIG. 3 shows a schematic cross-sectional view of an example cooling base and ESC.

FIG. 4 shows a schematic cross-sectional view of an example cooling base and ESC with a mechanical thermal brake.

FIG. 5 shows a schematic cross-sectional view of an example cooling base and ESC with a variable thermal brake.

FIG. 6A-C show schematic views of example cooling channel geometries.

FIG. 7 shows another schematic cross-sectional view of an example cooling base and ESC.

FIG. 8 shows an example computer system.

FIG. 9 is a flow diagram of an example process for additively manufacturing a cooling base.

Like reference numbers and designations in the various drawings indicate like elements.

### DETAILED DESCRIPTION

The present specification provides improved methods and assemblies for using additive manufacturing for fabricating a substrate support and/or components of the substrate support for use in substrate processing chambers. Embodiments of the present disclosure include cooling base design enabled by additive manufacturing that provides for the ability to maintain bonds with other substrate support components at low temperatures and without CTE mismatch and the ability to additively manufacture the cooling base with embedded features including fluid channels, conductive regions, thermal brake structures, and lift pin guides.

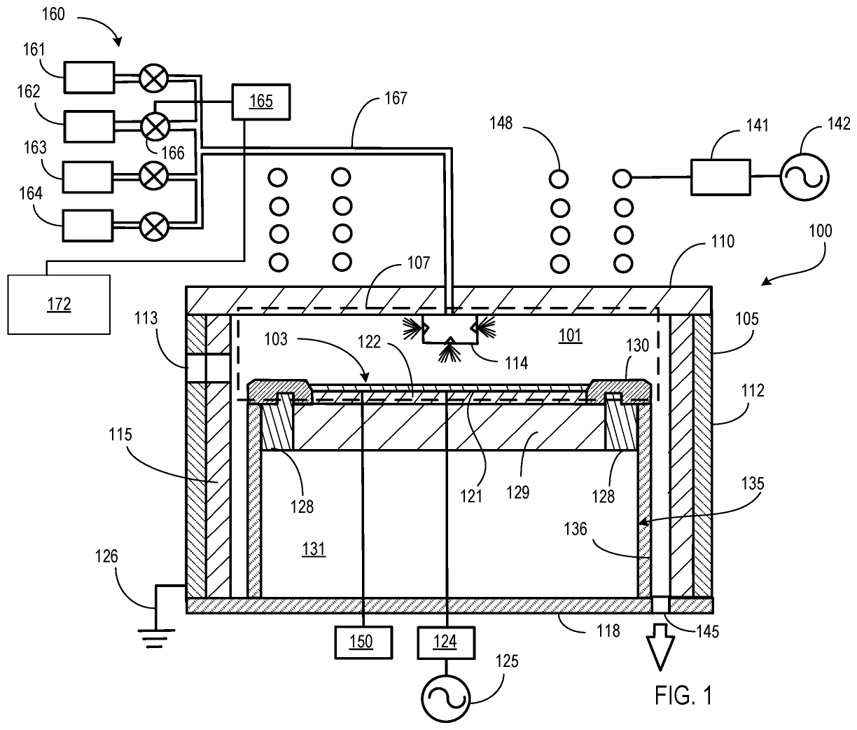

FIG. 1 illustrates a schematic cross-sectional view of an example processing chamber 100. In the example, the processing chamber is an etching chamber suitable for etching one or more material layer(s) disposed on a substrate 103 (e.g., also referred to as a “wafer”) in the processing chamber 100, e.g., a plasma processing chamber. The processing chamber 100 is provided for illustration and the substrate support including a cooling base can be used in other types of processing chambers. The processing chamber 100 includes a chamber body 105 defining a chamber volume 101 in which a substrate can be processed. The chamber body 105 has sidewalls 112 and a bottom 118 which are coupled with ground 126. The sidewalls 112 can include a liner 115 to protect the sidewalls 112 and extend the time between maintenance cycles of the plasma processing chamber 100. The chamber body 105 is supportive of a chamber lid assembly 110 to enclose the chamber volume 101. The chamber body 105 can be fabricated from, for example, aluminum, or other suitable materials. A substrate access port 113 is formed through the sidewall 112 of the chamber body 105, which can facilitate the transfer of the substrate 103 into and out of the plasma processing chamber 100. Access port 113 can be coupled with a transfer chamber and/or other chambers (not shown) of a substrate processing system, e.g., to perform other processes on the substrate. A pumping port 145 is formed through the bottom 118 of the chamber body 105 and connected to the chamber volume 101. A pumping device can be coupled through the pumping port 145 to the chamber volume 101 to evacuate and control the pressure within the processing volume. The pumping device can include one or more pumps and throttle valves.

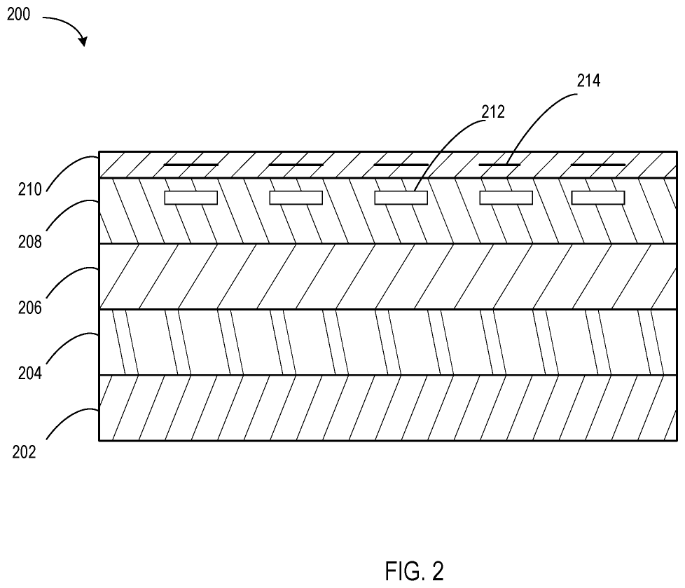

Chamber volume 101 includes a processing region 107, e.g., a station for processing a substrate. A substrate support 135 can be disposed in the processing region 107 of chamber volume 101 to support the substrate 103 during processing. The substrate support 135 can include an electrostatic chuck 122 for holding the substrate 103 during processing, a cooling base 129, and other support components 131 that are described in more detail below with respect to FIG. 2.

The electrostatic chuck (“ESC”) 122 can use electrostatic attraction to hold the substrate 103 to the substrate support 135. The ESC 122 can be powered by an RF or DC power supply 125 integrated with a match circuit 124. The ESC 122 can include an electrode 121 embedded within a dielectric body. The electrode 121 can be coupled with the RF or DC power supply 125 and can provide a bias which attracts plasma ions, formed from the process gases in the chamber volume 101, to the ESC 122 and substrate 103 seated on the pedestal. The RF or DC power supply 125 can cycle on and off, or pulse, during processing of the substrate 103. The substrate support 135 can include an isolator 128 for the purpose of making the sidewall of the ESC 122 less attractive to the plasma to prolong the maintenance life cycle of the ESC 122. Additionally, the substrate support 135 can have a cathode liner 136 to protect the sidewalls of the substrate support 135 from the plasma and to extend the time between maintenance of the plasma processing chamber 100.

Electrode 121 can be coupled with a DC power source 150. The power source 150 can provide a chucking voltage of about 5000 volts to about-5000 volts to the electrode 121. The power source 150 can also include a system controller for controlling the operation of the electrode 121 by directing a DC current to the electrode 121 for chucking and de-chucking the substrate 103. The ESC 122 can include heaters disposed within the ceramic and connected to a power source for heating the substrate, while a cooling base 129 supporting the ESC 122 can include conduits for circulating a heat transfer fluid to maintain a temperature of the ESC 122 and substrate 103 disposed thereon. The ESC 122 can be configured to perform in the temperature range required by the thermal budget of the device being fabricated on the substrate 103. For example, the ESC 122 can be configured to maintain the substrate 103 at a temperature of about−150° C. or lower to about 500° C. or higher depending on the process being performed. A cover ring 130 can be disposed on the ESC 122 and along the periphery of the substrate support 135. The cover ring 130 can be configured to confine etching gases to a desired portion of the exposed top surface of the substrate 103, while shielding the top surface of the substrate support 135 from the plasma environment inside the plasma processing chamber 100.

The additional support components 131 of the substrate support 135 can include a ground plate, an insulator body, and a facilities plate. FIG. 2, described below, illustrates an example schematic view illustrating multiple components of the substrate support 135. The substrate support can include lift pins disposed through openings formed in the substrate support (not shown). The lift pins can be coupled to actuators for raising and lowering the lift pins for positioning a substrate on the ESC, for example, for positioning the substrate on the ESC 122 after passing into the processing region through substrate access port 113.

Referring now to FIG. 1, a gas panel 160 (e.g., also referred to herein as “gas distribution manifold”) can be coupled by a gas line 167 with the chamber body 105 through chamber lid assembly 110 to supply process gases into the chamber volume 101. The gas panel 160 can include one or more process gas sources 161, 162, 163, 164 and can additionally include inert gases, non-reactive gases, and reactive gases, as can be used for any number of suitable processes. Examples of process gases that can be provided by the gas panel 160 include, but are not limited to, hydrocarbon containing gases including methane, sulfur hexafluoride, silicon chloride, silicon tetrachloride, carbon tetrafluoride, hydrogen bromide. Process gases that can be provided by the gas panel can include, but are limited to, argon gas, chlorine gas, nitrogen, helium, or oxygen gas, sulfur dioxide, as well as any number of additional materials. Additionally, process gasses can include nitrogen, chlorine, fluorine, oxygen, or hydrogen containing gases including, for example, BCl₃, C₂F+, C+F₈, C₄F₆, CHF₃, CH₂F₂, CH₃F, NF₃, NH₃, CO₂, SO₂, CO, N₂, NO₂, N₂O, and H₂, among any number of additional suitable precursors. Process gases from process gas sources, e.g., sources 161, 162, 163, 164, can be combined to form one or more etching gas mixtures. For example, gas panel 160 includes one or more process gas sources specific to oxide-based etching chemistries. In another example, gas panel 160 includes one or more process gas sources specific to nitride-based etching chemistries.

Gas panel 160 includes various valves, pressure regulators (not shown), and mass flow controllers (not shown) arranged with respect to the gas sources 161, 162, 163, 164 to control the flow of the process gases from the sources. Valves 166 can control the flow of the process gases from the sources 161, 162, 163, 164 from the gas panel 160. Operations of the valves, pressure regulators, and/or mass flow controllers can be controlled by a controller 165. Controller 165 can be operably coupled to an electro-valve (EV) manifold (not shown) to control actuation of one or more of the valves, pressure regulators, and/or mass flow controllers. The lid assembly 110 can include a gas delivery nozzle 114. The gas delivery nozzle 114 can include one or more openings for introducing the process gases from the sources 161, 162, 163, 164 of the gas panel 160 into the chamber volume 101. After the process gases are introduced into the plasma processing chamber 100, the gases can be energized to form a plasma. An antenna 148, such as one or more inductor coils, can be provided adjacent to the plasma processing chamber 100. An antenna power supply 142 can power the antenna 148 through a match circuit 141 to inductively couple energy, such as RF or DC energy, to the process gas to maintain a plasma formed from the process gas in the chamber volume 101 of the plasma processing chamber 100. Alternatively, or in addition to the antenna power supply 142, process electrodes below the substrate 103 and/or above the substrate 103 can be used to capacitively couple RF or DC power to the process gases to maintain the plasma within the chamber volume 101. The operation of the power supply 142 can be controlled by a controller, such as controller 165, that also controls the operation of other components in the plasma processing chamber 100.

The controller 165 can be used to control the process sequence, regulating the gas flows from the gas panel 160 into the plasma processing chamber 100, and other process parameters. Software routines, when executed by a computing device having one or more processors (e.g., a central processing unit (CPU)) in data communication with one or more memory storage devices, transform the computing device into a specific purpose computer such as a controller, which can control the plasma processing chamber 100 such that the processes are performed in accordance with the present disclosure. The software routines can also be stored and/or executed by one or more other controller(s) that can be associated with the plasma processing chamber 100.

In some embodiments, controller 165 is in data communication with a characterization device 172. Characterization device 172 can include one or more sensors (e.g., image sensors) operable to collect processing data related to processing chamber 100. For example, characterization device 172 includes an optical emission spectroscopy device configured to monitor a signal, e.g., emitted light of a plasma, within a processing region of the processing chamber 100. For example, a signal can be a primary or highest intensity wavelength of emitted light. Characteristics of the emitted light (e.g., wavelength and intensity) from the plasma within the processing region can depend in part on an etching gas mixture used to generate the plasma as well as a layer composition of the layer being etched. For example, each etching gas mixture and corresponding layer composition being etched can have a respective signal signature. Emitted wavelengths that are unique or distinguishing for each etching gas mixture and corresponding layer composition can be monitored to determine an etching condition of the layer being etched. For example, a thickness remaining of the layer being etched. Characteristics of the emitted light from the plasma can change, e.g., based on the etching process. For example, an intensity of a monitored signal can change as material is removed from the layer being processed. Characterization device 172 can be configured to collect processing data including the respective signals corresponding to the etching gas mixtures utilized in the wafer processing and corresponding layer compositions of the structure being processed in the processing chamber 100. Controller 165 can receive processing data from the characterization device 172 and determine, from the processing data, one or more actions to perform.

In some embodiments, at a termination point of etching process(es) for the wafer, an automatic or semi-automatic robotic manipulator (not shown) can be utilized to transfer the wafer(s) from the substrate support out of the process chamber, e.g., through substrate access port 113. For example, the robotic manipulator can transfer the wafer to another chamber (or another location) to perform another step in a fabrication process.

In some embodiments, a controller (e.g., controller 165) of a fabrication tool can execute a recipe including instructions for a fabrication process. The recipe can include temperature-control instructions executable by the controller 165 to control operations of various temperature-related components of the fabrication tool. For example, the temperature-related components can include (A) gas pressures introduced into each of the cooling regions of the ESC, (B) temperature settings for each of the multiple heaters with respective heating zones within the ceramic body of the ESC, (C) heater current settings for each of the microzone heaters within the ceramic body of the ESC, (D) coolant flow into cooling channels located in a base of the substrate support, or (E) any combination thereof. The recipe instructions can additionally include executable instructions related to other process parameters in addition to the operations of the ESC to operate components of the fabrication tool to control, for example, plasma power, flow of the etch gas, etc.

FIG. 2 shows a schematic cross-sectional view of an example support structure 200. The support structure 200 includes ground plate 202, insulator body 204, facilities plate 206, cooling base 208, and ESC 210.

The ground plate 202 can be formed of an electrically conductive material, e.g., a metal such as aluminum, and can be configured to be coupled to a bottom portion of the processing chamber (e.g., processing chamber 100 of FIG. 1). The ground plate 202 can be secured to the processing chamber as well as to affix other components of the substrate support to the ground plate, e.g., the facilities plate 206 or insulator body 204.

The insulator body 204 is formed of an insulating material, e.g., a polymeric material. The insulating material can include, for example, polymer (cross-linked polystyrene), polytetrafluoroethylene (PTFE), polyamide-imide (PAI), polyetheretherketone (PEEK), polyetherimide, polyphenylene sulfide, or a ceramic. In particular, the insulator body 204 can be configured to reduce the thermal and electrical interaction between the ESC 210 and the ground plate 202. For example, material of the insulator body can be selected based in part on an operating temperature of the fabrication processes (e.g., plasma etch processes), electrical properties, and/or radical compatibility (e.g., with plasma composition). Additionally, a thickness of insulator body can be selected to reduce a thermal and electrical interaction between the ground plate and the facilities plate/cooling base

The facilities plate 206 is coupled to the insulator body 204 and provides a pathway for connections (i.e., electrical, fluid, gas connections) to the cooling base 208 and the ESC 210. The facilities plate 206 can be formed from a metal, such as aluminum or stainless steel.

The cooling base 208 is coupled to the facilities plate. The cooling base 208 includes a temperature control structure embedded within the cooling base 208 for controlling a temperature of the ESC 210, when the ESC 210 is coupled to the cooling base 208. The temperature control structure can include cooling channels 212 for flowing a coolant fluid, or in the case of low temperature applications, a refrigerant fluid, e.g., a particular refrigerant. The cooling channels 212 can be coupled to a heat exchange device (not shown) for controlling the temperature of the fluid. The heat exchange device can be, for example, a heat exchanger or a chiller (including a set point chiller). The temperature control structures can also include gas conduits (not shown) for flowing gas (e.g., helium, nitrogen, or another gas) through the cooling base 208 and into the ESC 210. One or more seals can be disposed around the periphery of the cooling base and configured to prevent passage of a fluid between the cooling base and the facilities plate.

The ESC 210 is similar to the ESC 122 described with respect to FIG. 1 and can use electrostatic attraction to hold a substrate to the substrate support 200. The ESC 210 can include an electrode 214 embedded within a dielectric body. The electrode 214 can be coupled with an RF or DC power supply and can provide a bias which attracts plasma ions, formed from the process gases in the chamber volume, to the ESC 210 and the substrate seated on the ESC 210.

In some embodiments, the cooling base 208 is formed as a single structure, e.g., by additive manufacturing using a ceramic material, e.g., alumina (aluminum oxide, Al₂O₃). The cooling base 208 can be formed in a layer-by-layer process in which structures such as the temperature control structures as well as thermal brake structures can be formed or embedded during the additive manufacturing process, as described in more detail below.

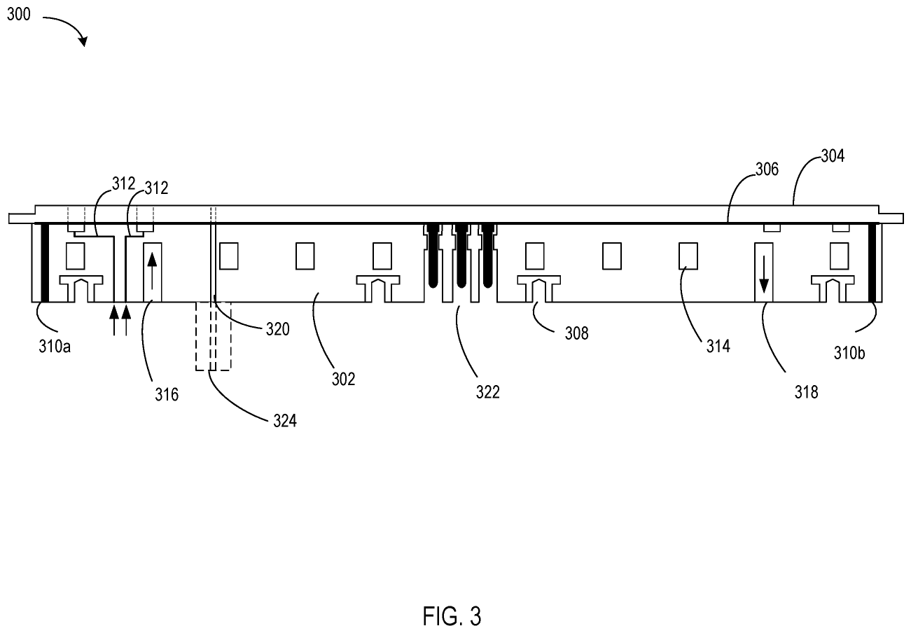

FIG. 3 shows a schematic cross-sectional view 300 of an example cooling base 302 and ESC 304. The cooling base 302 and ESC 304 are formed from materials having the same coefficient of thermal expansion (“CTE”). For example, they can be formed from the same material. In some implementations, both the cooling base 302 and the ESC 304 are formed from an insulator material such as a ceramic. In particular, both the base 302 and the ESC 304 can be formed from alumina. In other implementations, different ceramic materials can be used, for example, suitable ceramic materials such as Yttria (Yttria oxide Y₂O₃) or

Aluminum Nitride (AlN).

Having a common CTE allows for the cooling base 302 and ESC 304 to respond the same to changes in temperature. Thus, expansion or contraction of the components will not have a mismatch.

The cooling base 302 and the ESC 304 are coupled together by a bonding layer 306.

The bonding layer 306 can be formed from a metal such as aluminum. The metal bonding layer 306 allows for the bond to maintain performance at low temperatures including temperatures lower than typically available for other bonding materials such as elastomer bonds. However, using a metal bonding layer 306 may require the cooling base 302 and ESC 304 to have the same CTE, which is provided by the cooling base 302 and ESC 304 being formed from the same ceramic material.

The cooling base 302 can be formed in a substantially disk-shaped main portion having a substantially circular first surface that is coupled, through the bonding layer 306, to a corresponding surface of the ESC 304. The shape of the cooling base 302 aligns with the shape of the ESC 304, which in turn aligns with the shape of a mounted substrate. The selection of the ceramic material used to form the cooling base 302 can be based on materials suitable for the ESC 304 as well as suitability as to strength, durability, and heat transfer properties.

The cooling base 302 is further configured to be mounted at a substantially circular second surface of the disk-shaped cooling base to a facilities plate (not shown). The cooling base 302 includes anchors 308 for mounting the cooling base 302 to the facilities plate. In some implementations, the anchors 308 are threaded to receive a fastener or other threaded attaching structure of the facilities plate. The anchors 308 can be formed by drilling a hole in the ceramic cooling base 302 or through an additive manufacturing process that forms the anchor holes during fabrication. In some implementations, a threaded insert is then added to the anchor holes, for example, as formed from a plastic or metal material, that will then receive the attachment structure of the facilities plate. Although four anchors 308 are illustrated in FIG. 3, the number of anchors 308 may depend on the particular structural requirements and can be arranged in different locations on a surface of the cooling base 302. In some implementations, the threaded insert can be formed of an insulating or dielectric material with an embedded helical coil for receiving a threaded attachment structure and provide a stronger attachment with less risk of damage than threading the attaching structure directly into the ceramic material of the cooling base 302.

The cooling base 302 includes conductor paths 310a, 310b. Conductor paths 310a, 310b provide an electrically conductive path through the cooling base 302 from the facilities plate to the ESC 304. For example, the conductor paths 310a and 310b can electrically couple one or more power sources to one or more electrodes within the body of the ESC 304. In some implementations, the conductive paths 310a, 310b can be formed during additive manufacturing of the cooling base 302. For example, a particular region of the cooling base 302 corresponding to a conductor path can be formed using a doped ceramic to provide an electrical connection along the conductive path through the cooling base 302.

The cooling base 302 includes temperature control structures 312 and 314.

Temperature control structure 312 provides one or more pathways through the cooling base 302 and to the ESC 304. For example, the temperature control structure 312 can include one or more gas conduits for flowing gas (e.g., helium) though the cooling base 302 and into the ESC 304. The gas conduits can include multiple independent pathways or one or more branching pathways to provide the gas to the ESC 304. Multiple pathways can allow for finer control over cooling by routing controlled amounts of the gas to different regions of the ESC 304. As illustrated in FIG. 3, temperature control structure 312 includes two branches for providing cooling to two separate zones of the ESC 304. The ESC 304 includes pathways or other internal structures to distribute the gas, e.g., to a space between one or more surfaces of the ESC 304 and the substrate to provide wafer backside gas. Dashed lines merely illustrate that the paths pass through the ESC 304 and not a particular path geometry.

The temperature control structure 314 provides one or more cooling channels within the body of the cooling base 302. The cooling channels allow for a particular coolant or refrigerant fluid to circulate within the body of the cooling base 302. The refrigerant is cooled to a specified temperature using a chiller, e.g., a cryogenic chiller, prior to entering the substrate support and the cooling base 302 at an input point 316. The refrigerant is a suitable fluid that can be cooled to the specified temperature by the chiller, e.g.,-120 degrees Celsius. Circulating the refrigerant through the cooling channels between the input point 316 and an exit point 318 helps maintain the cooling base, and subsequently the adjacent ESC at a specified temperature. For example, the refrigerant can be circulated in a refrigeration loop such as a vapor-compression loop in which the refrigerant is cooled before entering the cooling base as a liquid or vapor fluid. The input point 316 and exit point 318 are coupled to a chiller to form a refrigerant loop. The chiller can control both a temperature of the refrigerant flowing to the cooling base as well as a flow rate. For example, the chiller can be configured to maintain a cryogenic temperature of an output refrigerant of at least-80 degrees Celsius.

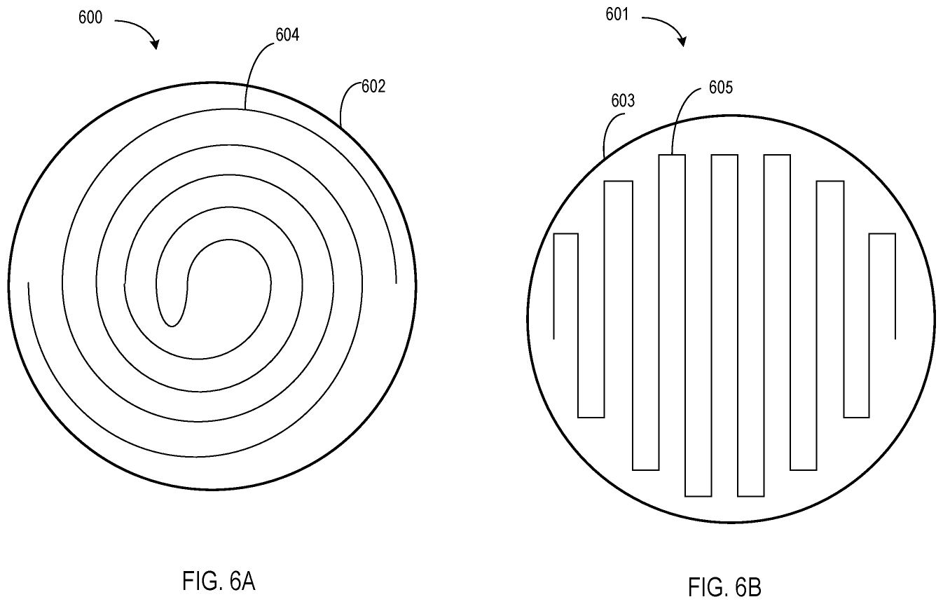

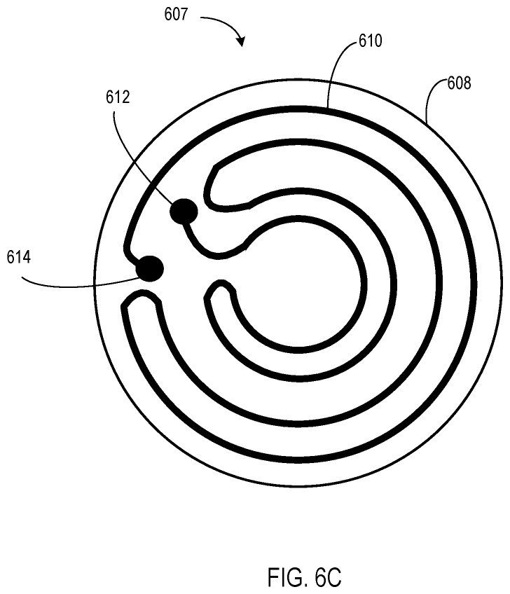

The cooling channels can have different and variable cross-sections taken perpendicular to the path of the cooling channel. For example, the cooling channels can have a circular, elliptical, or polygonal cross-sectional shape. Additionally, the cooling channels can have a cross-sectional area that increases or decreases at different positions. For example, reducing the cross-sectional area of a cooling channel at a particular region can increase velocity of the cooling fluid in that region, which affects the rate of thermal transfer, e.g., cooling to the local portion of the cooling base 302. The cooling channels can also have various two-or three-dimensional geometries within the body of the cooling base 302. Example cooling channel geometries within the cooling base 302 are described below with respect to FIG. 6.

Temperature control structures 312 and 314 can be formed through an additive manufacturing process in which the temperature control structures 312 and 314 are formed layer-by-layer with the cooling base 302. Using additive manufacturing allows for the formation of paths, e.g., for cooling channels, within the body of the cooling base that have sealed sidewalls which reduce the risk of fluid leaking. These paths can have input and output points formed at one or more surfaces of the cooling base. Using additive manufacturing also allows for complex geometries of cooling channels to be formed within the body of the cooling base 302.

The cooling base 302 also includes lift pin guides 320. Lift pin guides 320 provide a guide path through the cooling base 302 for respective lift pins. While FIG. 3 only illustrates one lift pin guide 320, the cooling base can include multiple lift pin guides disposed at particular locations in the body of the cooling base 302. For example, the cooling base 302 can include three lift pin guides, each positioned at equal angles from the center (e.g., 120 degrees apart). Lift pins pass though the cooling base 302 and the ESC 304 (illustrated by dashed lines), e.g., to lift the wafer off the ESC 304.

Lift pin guides 320 can be formed through additive manufacturing. The lift pin guides can be formed during manufacturing of the cooling base 302, for example, by adding layers that leave one or more openings for the lift pins. Fabricating the lift pin guides using additive manufacturing can provide tighter tolerances that reduce binding between lift pins and the lift pin guides during operation. In some alternative implementations, the cooling base is formed through additive manufacturing without the lift pin guides 320, which are then added at a later fabrication step, for example, by drilling pathways through the cooling base for the lift pins.

In some implementations, a portion of the cooling base surrounding each lift pin guide extends beyond an otherwise substantially planar surface of the cooling base 302 as illustrated by dashed region 324. In such an implementation, the lift pin guides can extend within the body of the facilities plate when the cooling base is mounted to the facilities plate.

The cooling base can also include feedthroughs 322. The feedthroughs 322 can be electrical feedthroughs for sensors, heater terminal leads, chucking electrode contact, etc. that pass through the cooling base 302.

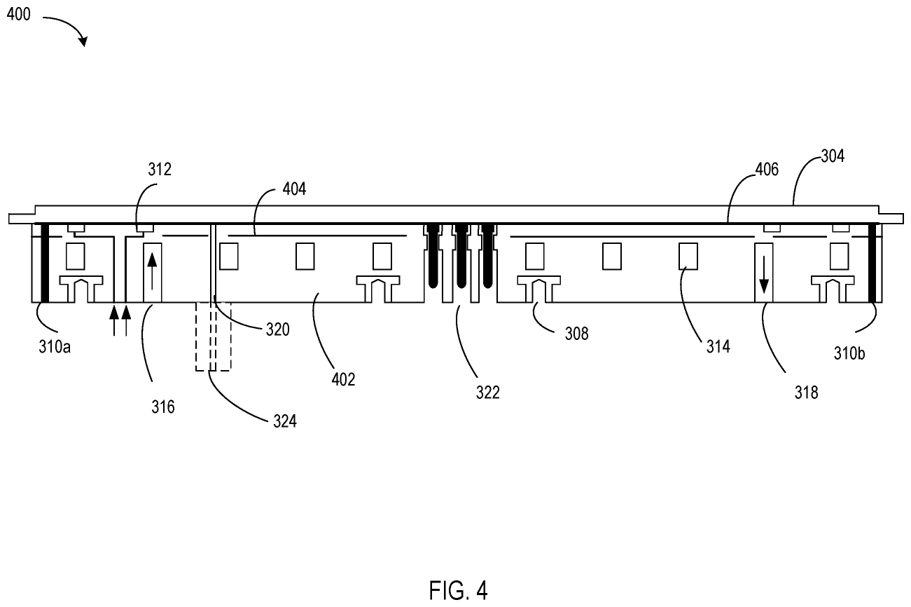

FIG. 4 shows a schematic cross-sectional view 400 of an example cooling base 402 and ESC 304 with a mechanical thermal brake 404. A thermal brake, which can also be referred to as a thermal isolator, is formed from a material that has a particular thermal conductivity to help spread thermal energy in a specified direction or to halt the spread in another direction. For example, a thermal brake can be formed of an insulator or dielectric material that hinders transmission of thermal energy across the insulating material.

In FIG. 4, the mechanical thermal brake 404 is positioned in parallel to a surface 406 of the cooling base 402 that is bonded to the ESC 304 and is positioned between the surface 406 and the temperature control structure 314. The mechanical thermal brake 404 can be formed of a material such as a graphite filament or graphite nanotubes that have a low degree of thermal conductivity. Other materials can be used that have suitable thermal transfer characteristics. In particular, in some implementations, the material is one that has different thermal conductivity along one axis than along other axes, e.g., a material having higher thermal conductivity along x-and y-axes than along z-axis or a lower conductivity along an axis orthogonal to one or more other axes.

The mechanical thermal brake 404 can thereby aid in the lateral spread of thermal energy for heating or cooling across the cooling base 402. For example, the cooling fluid passing through the cooling channels of the temperature control structure 314 transfers heat energy. The mechanical thermal brake helps ensure that the heat transfer is uniform and does not have temperature variations in the cooling base 402 based in part on the proximity to a given cooling channel path. This in turn helps provide uniform cooling to the ESC 304. The mechanical thermal brake 404 can be embedded within the body of the cooling base 402 during fabrication. For example, when forming the cooling base 402 using additive manufacturing, the thermal brake can be printed as a layer. In some other implementations, the mechanical thermal brake can be positioned on top of a printed layer of the cooling base and then the printing can continue with additional layers to embed to the mechanical thermal brake 404 within the body of the cooling base 402. In some implementations, the mechanical thermal brake is in the form of a thin sheet or mesh that substantially covers a surface of the cooling base layer and is positioned on that layer followed by additional ceramic layers of the cooling base. For example, for a disk-shaped cooling base, the mechanical thermal brake can be a circular sheet having a diameter substantially equal to or a specified amount less than the diameter of the circular surface of the cooling base.

The mechanical thermal brake 404 may be oriented within the body of the cooling base 402 in such a way that the material has good thermal conductivity in a lateral direction across a width of the disk-shaped cooling base 402; but has poorer thermal conductivity in a perpendicular direction.

In addition, the mechanical thermal brake can be configured to provide isolation between different temperature zones. For example, to provide different temperature zones within the cooling base and through to the ESC and wafer. For example, a particular wafer processing operation may specify an asymmetric temperature profile across the wafer, e.g., cooler at an edge region of the wafer than at a center region of the wafter. The mechanical thermal brake can be structured to prevent cross talk between temperature zones to facilitate temperature control for each zone. In some such implementations, the mechanical thermal brake can include additional perpendicular structures that define the temperature zones.

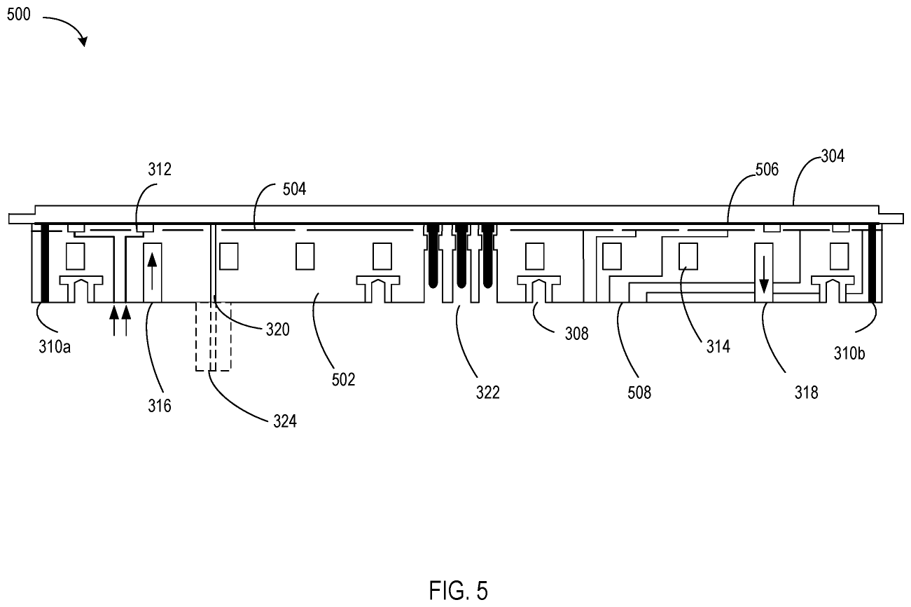

FIG. 5 shows a schematic cross-sectional view 500 of an example cooling base 502 and ESC 304 with a variable thermal brake 504. The variable thermal brake 504, similar to the mechanical thermal brake 404 in FIG. 4 is positioned in parallel to a surface 506 of the cooling base 502 that is bonded to the ESC 304 and is positioned between that surface 506 and the temperature control structure 314.

However, instead of providing a static mechanical thermal brake, the variable thermal brake 504 is formed from fluid pathways configured to hold a fluid, whether liquid or gas, having specified thermal transfer characteristics, e.g., helium or argon gases. Furthermore, separate fluid pathways can be provided to form different thermal brake zones that can have individually controlled fluid flow, and or pressure. In the example shown in FIG. 5 there are five separate thermal brake zones, each with a respective fluid input 508. Thus, for example, different amounts of helium can be provided to respective paths so that the ESC 304 can receive different amounts of cooling from the cooling plate 502. The use of the different fluid amounts to the respective thermal brake pathways allows for finer control over thermal conductance and temperature uniformity, e.g., as applied to the ESC 304 from the cooling base 502. The finer control allows for rapid and dynamic temperature adjustments as needed based on localized temperatures of the ESC 304.

The cooling channels within the cooling base can have various different geometries. These can include spiral geometries, linear geometries, and other shapes. In addition to allowing for complex geometries, when formed though additive manufacturing, the cooling channels can be formed close to other internal structures allowing for tighter tolerances between structures in the cooling base.

FIGS. 6A-C illustrate simplified examples of cooling channel geometries. FIG. 6A shows a schematic view 600 of an example cooling base 602. Example cooling base 602 includes a spiral cooling channel geometry 602. For a disk-shaped cooling base 602, the spiral cooling channel geometry 602 is illustrated from a cross sectional view through a circular side of the disk shape.

A refrigerant or coolant input is coupled to a first end of the spiral geometry and a refrigerant output is coupled to a second end of the spiral geometry. The refrigerant or coolant then circulates through the paths of the spiral cooling channel geometry 602 to provide cooling to the cooling base 602 and to an adjacent ESC bonded to a surface of the cooling base 602.

FIG. 6B shows a schematic view 601 of an example cooling base 603. Example cooling base 603 includes a linear cooling channel geometry 605. For a disk-shaped cooling base 603, the linear cooling channel geometry 605 is illustrated from a cross sectional view through a circular side of the disk shape. In particular, the linear cooling channel geometry 605 includes a number of linear segments that track a path back and forth across the cooling base 603.

A refrigerant or coolant input is coupled to a first end of the linear geometry and a refrigerant output is coupled to a second end of the linear geometry. The refrigerant or coolant then circulates through the paths of the linear cooling channel geometry 605 to provide cooling to the cooling base 603 and to an adjacent ESC bonded to a surface of the cooling base 603.

FIG. 6C shows a schematic view 607 of an example cooling base 608. Example cooling base 608 includes a recursive loop channel geometry 610. For a disk-shaped cooling base 608, the recursive loop channel geometry 610 is illustrated from a cross sectional view through a circular side of the disk shape.

A refrigerant or coolant input 612 is coupled to a first end of the recursive loop channel and a refrigerant or coolant output 614 is coupled to a second end of the recursive loop channel. The refrigerant or coolant then circulates though the paths of the recursive loop channel geometry 610 to provide cooling. The recursive loop channel geometry 610 can help reduce localized temperature differences, e.g., cold spots, within the cooling base 608 and subsequently as transferred to the ESC and wafer.

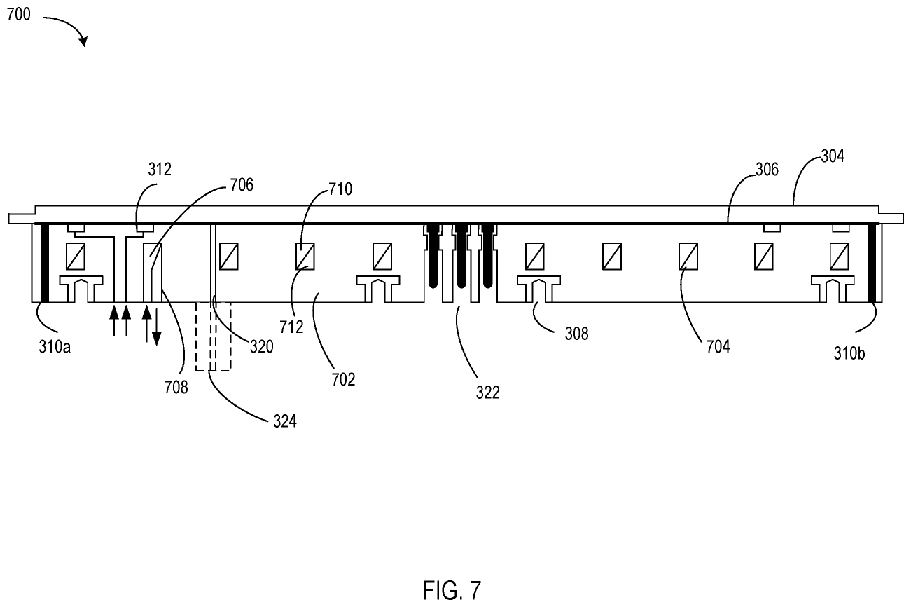

FIG. 7 shows another schematic cross-sectional view 700 of an example cooling base 702 and ESC 304. The cooling base 702 is bonded to the ESC 304 with metallic bond 306 similarly as described above with respect to FIG. 3. Additionally, cooling base 702 includes similar features as in FIG. 3 including lift pin guide 320, conductor paths 310a, 310b, and temperature control structure 312.

The temperature control structure 704 provide cooling channels within the body of the cooling base 702. The cooling channels allow for a particular refrigerant or coolant fluid to circulate within the body of the cooling base 702. In particular, the cooling channels 704 are formed from adjacent input and output paths such that the refrigerant circulates from an input point 706, through the cooling channels, and out an output point 708, which is adjacent to the input point 706. For example, the cooling channels can be formed as stacked triangular cross-sectional paths that combined form a rectangular shape. Input refrigerant flows through an “upper” cooling channel 710 having a large surface area facing the ESC 304, allowing the refrigerant to transfer cooling more efficiently to the ESC 304 while the refrigerant is at the coolest temperature and returning on the “lower” channel 712 that has a larger surface area opposite the side of the ESC 304.

### Additive Manufacturing

In some embodiments, substrate support design can be selected to improve substrate processing including adapting various design parameters for the substrate support. Relationships between the various design parameters in a substrate support design can be complex, where a design parameter may affect one or more other design parameters. Adapting the various design parameters into a design can yield a unique solution for a substrate support to improve process uniformity (e.g., temperature uniformity) during a fabrication process. Moreover, as discussed in further detail below, additive manufacturing techniques can be used instead of, or in addition to, traditional, non-additive manufacturing techniques to expand a design window of what fabricated designs are possible to implement.

In some embodiments, additive manufacturing (e.g., 3D printing) processes can be used to facilitate a design space for a cooling base. As depicted in FIGS. 3-7, various subcomponents of the cooling base can be enabled by additive manufacturing techniques, one or more of which may not be otherwise achievable by traditional manufacturing techniques.

For example, the cooling base can be fabricated by forming layers of a ceramic material that are the same as the ceramic material used to form an ESC. Using the same material provides a common CTE, which allows for the use of a metallic bond between the cooling base. Using a metallic bond between the cooling base and the ESC facilities lower temperature substrate processing operations than elastomer bonds.

The cooling base can include regions of internal geometries, e.g., 3D printed lattice infill patterns, rather than a solid structure if the lattice structures provide specified thermal characteristics and structural strength. Example infill geometries include honeycomb, crossbeam, gyroid, etc. The use of infill patterns reduces material costs while maintaining the required functionality of the cooling base.

The cooling base can include internal features, for example, cooling channels, gas conduits, isolation features, electrical connections, etc., formed by an additive manufacturing process and without requiring e.g., welding/brazing steps. Using additive manufacturing techniques allows for greater control over the geometries of cooling channels and gas conduits including path geometries and cross-sectional shape including variations in the shape and diameter of the cooling paths. Using additive manufacturing to form paths with sealed sidewalls within the body of the cooling base reduces leakage and failure points within the cooling base. Forming the cooling paths and gas conduits within the body of the cooling base using additive manufacturing can also improve a thermal conductance between the fluids passing through the cooling paths and the body of the cooling base.

The isolation features, e.g., thermal brakes, can be formed or embedded during the additive manufacturing process. For example, a material for a mechanical thermal brake, e.g., as depicted in FIG. 4, can be deposited on an additively manufactured layer, and printed over with additional layers. In another example, gas channels for a variable thermal brake including one or more zones, as depicted in FIG. 5, can be formed during the additive manufacturing process.

Conductive paths can be formed during the additive manufacturing process by doping a region of a layer being formed with a conductive material. Forming the conductive paths during additive manufacturing eliminates additional processing steps to add conductive materials to a fabricated cooling base and provides for stricter tolerances that avoids gaps or other flaws that could hamper performance of the cooling base or overall substrate support structure.

In some implementations, lift pin guides are also formed within the body of the cooling base during additive manufacturing. The lift pin guides formed during additive manufacturing can have stricter tolerances and can reduce a likelihood of binding between lift pins and the lift pin guides during operation.

In some embodiments, additive manufacturing e.g., three-dimensional printing (or 3-D printing), may be used to produce (or make) the substrate support and components described herein. In one embodiment, a computer (CAD) model of the required part is first made and then a slicing algorithm maps the information for every layer. A layer starts off with a thin distribution of powder spread over the surface of a powder bed. A chosen binder material then selectively joins particles where the object is to be formed. Then a piston which supports the powder bed and the part-in-progress is lowered for the next powder layer to be formed. After each layer, the same process is repeated followed by a final heat treatment to make the object. Since 3-D printing can exercise local control over the material composition, microstructure, and surface texture, various (and previously inaccessible) geometries may be achieved with this method.

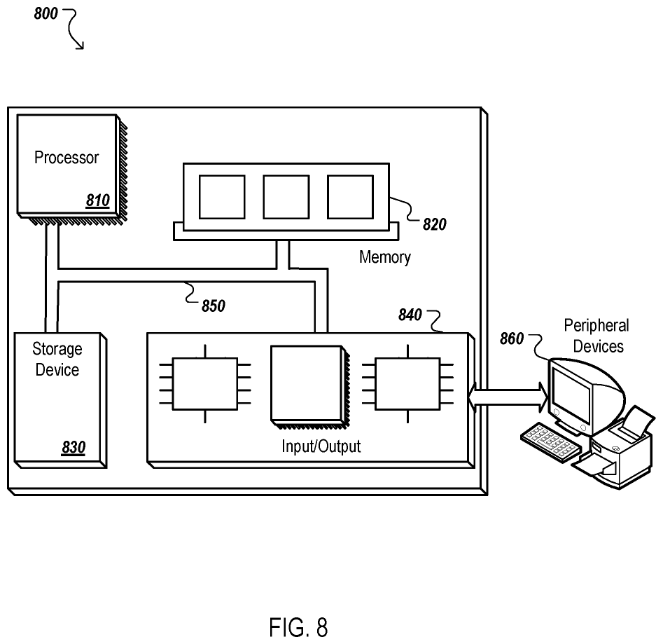

In one embodiment, a substrate support, and components of a substrate support, e.g., a cooling base, as described herein may be represented in a data structure readable by a computer rendering device or a computer display device. FIG. 8 is a schematic representation of a computer system with a computer-readable medium according to one embodiment. The computer-readable medium may contain a data structure that represents the cooling base. The data structure may be a computer file, and may contain information about the structures, materials, textures, physical properties, or other characteristics of one or more articles. The data structure may also contain code, such as computer executable code or device control code that engages selected functionality of a computer rendering device or a computer display device. The data structure may be stored on the computer-readable medium. The computer readable medium may include a physical storage medium such as a magnetic memory, floppy disk, or any convenient physical storage medium. The physical storage medium may be readable by the computer system to render the article represented by the data structure on a computer screen or a physical rendering device which may be an additive manufacturing device, such as a 3D printer.

In some embodiments, additive manufacturing techniques can be used in combination with other manufacturing techniques, e.g., subtractive manufacturing. For example, subtractive manufacturing can be used to modify/remove portions of the cooling base and additive manufacturing can be used to add/modify portions of the cooling base. The combination of techniques can be used during the initial process to manufacture or to modify/refurbish/regrow an existing cooling base or components of a substrate support to repair damage or change a configuration of the features.

In some embodiments, additive manufacturing techniques can be used to regrow/refurbish portions of a cooling base, e.g., to repair operational damage or manufacturing damage, and/or to add features.

In some embodiments, additive manufacturing techniques can include ceramic-based additive manufacturing including a binder, e.g., a polymer binder, to form a slurry including a ceramic powder and where a photosensitizer can be included in the slurry that is sensitized (e.g., is curable by) to a wavelength of light. For example, a photopolymerization technique using ultraviolet (UV) light can be used to form a ceramic green body, which can then be consolidated into a ceramic part from the green body using a sintering process.

In some embodiments, additive manufacturing techniques can include a coating process, where layers of a body are formed in a layer-by-layer process using coating techniques, e.g., plasma spray coating, screen printing, etc. Plasma spray coating process can be used to coat an exposed surface from a powder, e.g., a ceramic powder, metal powder, or a combination of ceramic and metallic powder. Screen printing can be used to form, for example, metal-based electrodes as described in this specification.

In some embodiments a sintering (e.g., firing) process can be used to consolidate the ceramic powder/particles (e.g., remove porosity and densify the ceramic material) of a green state ceramic part. For example, a sintering process can be performed at a high temperature below a melting point of the ceramic material(s) where the material of the separate particles diffuse towards neighboring power particles to form a densify ceramic body. In some embodiments, the sintering process includes a pre-heat process to remove organic materials, e.g., polymer(s), lubricant, binders, etc. In some embodiments, the sintering process includes a cooling process to cool down the ceramic parts to reduce cracking/stress formation.

In some embodiments, a rapid sintering process, e.g., a flash sintering process, can be performed on a set of green ceramic layers of a green ceramic body. For example, a sintering process can be alternated with a forming/additive manufacturing process, where a set number of layers are formed by additive manufacturing and then sintered in sequence before another set of layers are formed by additive manufacturing on the exposed surface of the body. In other words, portions of the ceramic body are formed in a green state and sintered in succession, where an end result of the process is a densified ceramic body.

In some embodiments, a refurbished part can be sintered such that the regrown layers of the refurbishing process are densified, e.g., to match characteristics of the original part.

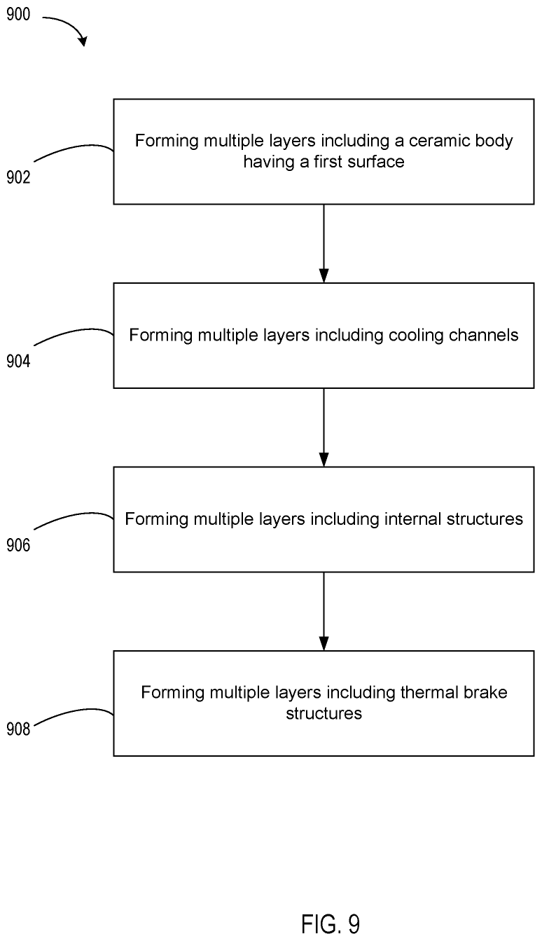

FIG. 9 is a flow diagram of an example process 900 for manufacturing a substrate support component for substrate processing, and in particular manufacturing a cooling base. For convenience, the process 900 will be described with respect to an additive manufacturing system that performs at least some steps of the process.

An additive manufacturing system forms multiple layers including a ceramic body having a first surface (902). The additive manufacturing system can receive, from a computer system, a data structure representative of the cooling base, and use the data structure to form the multiple layers of the cooling base. Forming the multiple layers of the ceramic body can include forming one or more infill structures, e.g., lattices, within the ceramic body.

The additive manufacturing system forms multiple layers including one or more cooling channels arranged according to a geometry specified by the data structure (904).

The additive manufacturing system forms multiple layers including one or more internal structures of the cooling base (906). The internal structures can include conductive paths, gas flow conduits, and lift in guides.

The additive manufacturing system forms multiple layers for providing thermal brake structures (908). Providing the thermal brake structures can include forming one or more fluid conduits using the multiple layers. Providing the thermal brake structures can also include embedding another material within the multiple layers including depositing or placing a material at particular locations on a layer of the multiple layers, e.g., graphite, and then forming additional layers on top of the material.

FIG. 8 is a block diagram of an example computer system 800 that can be used to perform operations described above. For example, such as operations performed by the additive manufacturing system. The system 800 includes a processor 810, a memory 820, a storage device 830, and an input/output device 840. Each of the components 810, 820, 830, and 840 can be interconnected, for example, using a system bus 850. The processor 810 is capable of processing instructions for execution within the system 800. In one implementation, the processor 810 is a single-threaded processor. In another implementation, the processor 810 is a multi-threaded processor. The processor 810 is capable of processing instructions stored in the memory 820 or on the storage device 830.

The memory 820 stores information within the system 800. In one implementation, the memory 820 is a computer-readable medium. In one implementation, the memory 820 is a volatile memory unit. In another implementation, the memory 820 is a non-volatile memory unit.

The storage device 830 can provide mass storage for the system 800. In one implementation, the storage device 830 is a computer-readable medium. In various different implementations, the storage device 830 can include, for example, a hard disk device, an optical disk device, a storage device that is shared over a network by multiple computing devices (e.g., a cloud storage device), or some other large capacity storage device.

The input/output device 840 provides input/output operations for the system 800. In one implementation, the input/output device 840 can include one or more of a network interface device, e.g., an Ethernet card, a serial communication device, e.g., and RS-232 port, and/or a wireless interface device, e.g., and 802.11 card. In another implementation, the input/output device can include driver devices configured to receive input data and send output data to peripheral devices 860, e.g., keyboard, printer, and display devices. Other implementations, however, can also be used, such as mobile computing devices, mobile communication devices, set-top box television client devices, etc.

Although an example processing system has been described in FIG. 8, implementations of the subject matter and the functional operations described in this specification can be implemented in other types of digital electronic circuitry, or in computer software, firmware, or hardware, including the structures disclosed in this specification and their structural equivalents, or in combinations of one or more of them.

Aspects of the subject matter and the actions and operations described in this specification, for example, computing devices such as controller 165 and processes performed by controller 165 such as controlling switching of etching gasses of a plasma processing chamber, controlling cooling and heating processes, etc., can be implemented in digital electronic circuitry, in tangibly-embodied computer software or firmware, in computer hardware, including the structures disclosed in this specification and their structural equivalents, or in combinations of one or more of them. The subject matter and the actions and operations described in this specification can be implemented as or in one or more computer programs, e.g., one or more modules of computer program instructions, encoded on a computer program carrier, for execution by, or to control the operation of, data processing apparatus. The carrier can be a tangible non-transitory computer storage medium. Alternatively, or in addition, the carrier can be an artificially-generated propagated signal, e.g., a machine-generated electrical, optical, or electromagnetic signal, which is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

The term “data processing apparatus” encompasses all kinds of apparatus, devices, and machines for processing data, including by way of example a programmable processor, a computer, or multiple processors or computers. Data processing apparatus can include special-purpose logic circuitry, e.g., an FPGA (field programmable gate array), an ASIC (application-specific integrated circuit), or a GPU (graphics processing unit). The apparatus can also include, in addition to hardware, code that creates an execution environment for computer programs, e.g., code that constitutes processor firmware, a protocol stack, a database management system, an operating system, or a combination of one or more of them.

A computer program can be written in any form of programming language, including compiled or interpreted languages, or declarative or procedural languages; and it can be deployed in any form, including as a stand-alone program, e.g., as an app, or as a module, component, engine, subroutine, or other unit suitable for executing in a computing environment, which environment can include one or more computers interconnected by a data communication network in one or more locations.

A computer program can, but need not, correspond to a file in a file system. A computer program can be stored in a portion of a file that holds other programs or data, e.g., one or more scripts stored in a markup language document, in a single file dedicated to the program in question, or in multiple coordinated files, e.g., files that store one or more modules, sub-programs, or portions of code.

The processes and logic flows described in this specification can be performed by one or more computers executing one or more computer programs to perform operations by operating on input data and generating output. The processes and logic flows can also be performed by special-purpose logic circuitry, e.g., an FPGA, an ASIC, or a GPU, or by a combination of special-purpose logic circuitry and one or more programmed computers.

Computers suitable for the execution of a computer program can be based on general or special-purpose microprocessors or both, and any other kind of central processing unit. Generally, a central processing unit will receive instructions and data from a read-only memory or a random-access memory or both. The essential elements of a computer are a central processing unit for executing instructions and one or more memory devices for storing instructions and data. The central processing unit and the memory can be supplemented by, or incorporated in, special-purpose logic circuitry.

Generally, a computer will also include, or be operatively coupled to, one or more mass storage devices, and be configured to receive data from or transfer data to the mass storage devices. The mass storage devices can be, for example, magnetic, magneto-optical, or optical disks, or solid-state drives. However, a computer need not have such devices. Moreover, a computer can be embedded in another device, e.g., a mobile telephone, a personal digital assistant (PDA), a mobile audio or video player, a game console, a Global

Positioning System (GPS) receiver, or a portable storage device, e.g., a universal serial bus (USB) flash drive, to name just a few.

To provide for interaction with a user, the subject matter described in this specification can be implemented on one or more computers having, or configured to communicate with, a display device, e.g., a LCD (liquid crystal display) monitor, or a virtual-reality (VR) or augmented-reality (AR) display, for displaying information to the user, and an input device by which the user can provide input to the computer, e.g., a keyboard and a pointing device, e.g., a mouse, a trackball or touchpad. Other kinds of devices can be used to provide for interaction with a user as well; for example, feedback and responses provided to the user can be any form of sensory feedback, e.g., visual, auditory, speech or tactile; and input from the user can be received in any form, including acoustic, speech, or tactile input, including touch motion or gestures, or kinetic motion or gestures or orientation motion or gestures. In addition, a computer can interact with a user by sending documents to and receiving documents from a device that is used by the user; for example, by sending web pages to a web browser on a user's device in response to requests received from the web browser, or by interacting with an app running on a user device, e.g., a smartphone or electronic tablet. Also, a computer can interact with a user by sending text messages or other forms of message to a personal device, e.g., a smartphone that is running a messaging application, and receiving responsive messages from the user in return.

This specification uses the term “configured to” in connection with systems, apparatus, and computer program components. That a system of one or more computers is configured to perform particular operations or actions means that the system has installed on it software, firmware, hardware, or a combination of them that in operation cause the system to perform the operations or actions. That one or more computer programs is configured to perform particular operations or actions means that the one or more programs include instructions that, when executed by data processing apparatus, cause the apparatus to perform the operations or actions. That special-purpose logic circuitry is configured to perform particular operations or actions means that the circuitry has electronic logic that performs the operations or actions.

While this specification contains many specific implementation details, these should not be construed as limitations on the scope of what is being claimed, which is defined by the claims themselves, but rather as descriptions of features that can be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features can be described above as acting in certain combinations and even initially be claimed as such, one or more features from a claimed combination can in some cases be excised from the combination, and the claim can be directed to a subcombination or variation of a subcombination.

Similarly, while operations are depicted in the drawings and recited in the claims in a particular order, this by itself should not be understood as requiring that such operations be performed in the particular order shown or in sequential order, or that all illustrated operations be performed, to achieve desirable results. In certain circumstances, multitasking and parallel processing can be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing can be advantageous.

What is claimed is:

1. A substrate support assembly comprising:
an electrostatic chuck; and
a cooling base having a first surface that is bonded to a first surface of the electrostatic chuck with a metallic bonding material, the cooling base comprising:
a ceramic body having a coefficient of thermal expansion substantially the same as the electrostatic chuck;
one or more cooling channels formed within the ceramic body; and
one or more conductor paths extending through the ceramic body from the first surface to a second surface on an opposite side of the cooling base.

2. The substrate support assembly of claim 1, further comprising;
a mechanical thermal brake structure embedded within the ceramic body of the cooling base, the mechanical thermal brake structure configured to provide lateral temperature uniformity across the cooling base.

3. The substrate support assembly of claim 1, further comprising;
a plurality of fluid pathways forming a variable thermal brake structure, each fluid pathway corresponding to a particular zone, wherein each zone is individually controllable to provide a specified degree of thermal isolation.

4. The substrate support assembly of claim 1, wherein the one or more cooling channels comprise a first cooling channel oriented to provide a first surface area oriented to the first surface of the cooling base and a second cooling channel positioned adjacent to the first cooling channel and further from the first surface than the first cooling channel, wherein the a refrigerant inflow is provided to the first cooling channel and a refrigerant outflow is provided from the second cooling channel.

5. The substrate support assembly of claim 1, further comprising:
a plurality of lift pin guides integrated within, and extending through, the ceramic body, each lift pin guide configured to receive a lift pin.

6. The substrate support assembly of claim 1, wherein the cooling base further comprises a lattice infill region defining a volume within the ceramic body.

7. A substrate support component of a substrate support embodied in a machine-readable medium for designing, manufacturing, or testing a design, the substrate support component comprising:
a cooling base wherein the cooling base is configured to support an electrostatic chuck on a first surface of the cooling base;
one or more cooling channels embedded within the cooling base and configured to facilitate refrigerant flow within the cooling base;
one or more first gas conduits formed within the cooling base and configured to facilitate gas flow through the cooling base and couple into one or more second gas conduits of the electrostatic chuck, when the electrostatic chuck is supported by the first surface; and
one or more thermal isolation structures integrally formed within the cooling base and oriented to control thermal uniformity across the cooling base as provided by the refrigerant flowing through the one or more cooling channels.

8. The substrate support component embodied in the machine-readable medium of claim 7, wherein the one or more thermal isolation structures comprise a mechanical thermal break formed from a material having different thermal conduction along at least two orthogonal axes.

9. The substrate support component embodied in the machine-readable medium of claim 7, wherein the one or more thermal isolation structures comprise a plurality of independent fluid pathways configured to receive a controlled amount of gas flow.

10. The substrate support component embodied in the machine-readable medium of claim 7, wherein a first surface of the cooling base is configured to retain an electrostatic chuck and a second, opposing surface of the cooling base is configured to affix to a facilities component of the substrate support.

11. The substrate support component embodied in the machine-readable medium of claim 7, further comprising one or more conductor paths extending from the first surface of the cooling base to a second, opposing surface of the cooling base, wherein each of the one or more conductor paths is formed through doping of a material being deposited within a specified region of a respective layer of the cooling base with an electrically conductive material.

12. The substrate support component embodied in the machine-readable medium of claim 7, wherein the one or more thermal isolation structures are arranged with respect to the cooling base to provide a specified lateral temperature uniformity across the cooling base.

13. The substrate support component embodied in the machine-readable medium of claim 7, wherein the substrate support component resides on storage medium as a data format used for an exchange of layout data.

14. A method of manufacturing a substrate support, the method comprising:
forming, by an additive manufacturing system, a plurality of layers, the plurality of layers comprising:
a ceramic body;
one or more cooling channels formed within the ceramic body and configured to circulate a refrigerant;
one or more gas conduits formed within the ceramic body and configured to pass a gas through the ceramic body; and
one or more conductor paths formed within the ceramic body and extending from a first surface of the substrate support to a second, opposing surface of the ceramic body.

15. The method of claim 14, further comprising:
embedding a thermal isolation structure between layers of the plurality of layers, the thermal isolation structure comprising a sheet of material providing a mechanical thermal brake.

16. The method of claim 15, wherein the sheet of material is formed form a material different than the ceramic body and having different thermal characteristics along at least two different axes of the ceramic body.

17. The method of claim 14, wherein the plurality of layers further comprises:
one or more fluid pathways formed within the ceramic body and configured to provide a variable thermal brake when a particular amount of fluid is provided within the one or more fluid pathways.

18. The method of claim 14, wherein the one or more conductor paths are formed by doping the plurality of layers within the respective regions with an electrically conductive material.

19. The method of claim 14, wherein the plurality of layers further comprise:
one or more lift pin guides formed within the ceramic body, the one or more lift pin guides each providing a through hole extending from a first surface of the substrate support to a second, opposing surface of the ceramic body.

20. The method of claim 14, wherein the plurality of layers further comprise:
forming one or more regions of the ceramic body as an interior lattice structure of ceramic material.
